(19) United States
(12) Patent Application Publication
(10) Pub. No.: US 2024/0179859 A1
(43) Pub. Date: May 30, 2024

(54) Trimless Foldable Displays

(71) Applicant: Google LLC, Mountain View, CA (US)

(72) Inventors: Yiting Liu, New Taipei City (TW); Yongho Lim, Kildeer, IL (US); Avi Pinchas Hecht, San Francisco, CA (US); Michael J. Lombardi, South Barrington, IL (US)

(73) Assignee: Google LLC, Mountain View, CA (US)

(21) Appl. No.: 18/434,210

(22) Filed: Feb. 6, 2024

Related U.S. Application Data
(60) Provisional application No. 63/605,256, filed on Dec. 1, 2023.

(51) Int. Cl. H05K 5/02

(52) U.S. Cl. CPC H05K 5/0217

(57) ABSTRACT

This document describes systems and techniques directed at trimless foldable displays. In aspects, a foldable electronic device includes a foldable display structure having a cover layer and a display panel positioned thereunder. At least portions of the cover layer may extend beyond one or more edges of the display panel. The foldable electronic device may further include a first compliant material disposed (i) between the housing and the display panel and (ii) underneath the at least portions of the cover layer that extend beyond the one or more edges of the display panel. Through such an implementation, the display panel of the foldable electronic device may be protected by the cover glass and/or the first compliant material. As a result, the foldable electronic device can do away with a display trim that would otherwise surround a perimeter of the display.

### CROSS-REFERENCE TO RELATED APPLICATION(S)

This application claims the benefit of U.S. Provisional Patent Application Ser. No. 63/605,256 filed on Dec. 1, 2023, the disclosure of which is incorporated by reference herein in its entirety.

### SUMMARY

This document describes systems and techniques directed at trimless foldable displays. In aspects, a foldable electronic device includes a foldable display structure having a cover layer and a display panel positioned thereunder. At least portions of the cover layer may extend beyond one or more edges of the display panel. The foldable electronic device may further include a first compliant material disposed (i) between the housing and the display panel and (ii) underneath the at least portions of the cover layer that extend beyond the one or more edges of the display panel. Through such an implementation, the display panel of the foldable electronic device may be protected by the cover glass and/or the first compliant material. As a result, the foldable electronic device can do away with a display trim that would otherwise surround a perimeter of the display.

In aspects, a foldable electronic device is disclosed that includes a housing having a first folding region that intersects a first non-folding region and a second non-folding region. At least one of the first non-folding region or the second non-folding region is configured to rotate about the first folding region. The foldable electronic device further includes a foldable display structure positioned within at least portions of the first non-folding region and the second non-folding region of the housing. The foldable display structure includes (i) a display panel having a top face within which a plurality of light-emitting pixels are disposed and (ii) a cover layer positioned as the topmost layer of a foldable display structure. The cover layer includes a top face and a bottom face. The bottom face of the cover layer has an area larger than an area of the top face of the display panel such that at least portions of the cover layer extend beyond one or more edges of the display panel. The foldable electronic device further includes a first compliant material disposed (i) between the housing and the display panel and (ii) underneath the at least portions of the cover layer that extend beyond the one or more edges of the display panel.

This Summary is provided to introduce simplified concepts of systems and techniques directed at trimless foldable displays, the concepts of which are further described below in the Detailed Description and Drawings. This Summary is not intended to identify essential features of the claimed subject matter, nor is it intended for use in determining the scope of the claimed subject matter.

### BRIEF DESCRIPTION OF THE DRAWINGS

The details of one or more aspects of systems and techniques directed at trimless foldable displays are described in this document with reference to the following drawings:

FIG. 1-1 illustrates a foldable electronic device with an open-design hinge mechanism;

FIG. 1-2 illustrates a foldable electronic device with a trim surrounding a perimeter of a display;

FIG. 2 illustrates an example implementation of an example foldable electronic device with a trimless foldable display in accordance with one or more implementations;

FIG. 3 illustrates example foldable electronic devices in which trimless foldable displays can be implemented;

FIG. 4 illustrates three example section views of the example foldable electronic device with a trimless foldable display in accordance with one or more implementations;

FIG. 5 illustrates two example implementations for a foldable electronic device having a compliant material in accordance with one or more implementations;

FIG. 6 illustrates three example implementations of the cover layer in accordance with one or more implementations; and

FIG. 7 illustrates an example implementation of the display with more detail in accordance with one or more implementations.

The same numbers are used throughout the Drawings to reference like features and components.

### DETAILED DESCRIPTION

### Overview

Many electronic devices include displays, such as light-emitting diode (LED) displays or liquid crystal displays (LCDs). Electronic device manufacturers often fabricate displays in a layered structure (“display panel stack”). The display panel stack includes a display module having a display panel that, when integrated into an electronic device, is disposed underneath and shielded by a cover layer (e.g., a glass layer). The display panel stack may further include one or more of a touch layer (e.g., touch sensor panel), a polarizer layer (e.g., polarization filters), an adhesive layer, and/or a protective layer (e.g., an EMBO layer).

The protective layer may include one or more sublayers, such as a polymer sublayer (e.g., polyethylene terephthalate (PET) substrate), a metallic sublayer (e.g., copper, stainless steel), a foam pad (e.g., to absorb compressive forces during manufacturing or usage), and an adhesive sublayer. The protective layer shields delicate display panels from both mechanical and electromagnetic forces, as well as from thermal radiation.

Any physical or electrical damage to a display panel can quickly render portions of the display panel inoperable, spoiling user experience. Thus, display panels are handled with great care during manufacturing and are often surrounded by many shielding components, including the protective layer and the cover layer, for protection during manufacturing and/or device usage. Not only are display panels delicate, but they are also elaborate, requiring sophisticated manufacturing techniques to intricately design an array of pixel circuits within the display of the display module. Pixel arrays include tens of thousands of pixels organized into a two-dimensional grid (e.g., a circular or rectangular grid). Each of the pixel circuits may include an organic light-emitting diode (“pixel”) composed of, for example, a red sub-pixel, a green sub-pixel, and/or a blue sub-pixel. To power and control the pixel array, display modules often include routing circuitry, surrounding a perimeter of the pixel array, connecting the pixels to one or more drivers. In one example, a pixel array having a two-dimensional rectangular grid of pixels is operably coupled to one or more row-line drivers via electrical traces (e.g., wires). Electronic devices can, via the one or more drivers, control any of the pixels within a display panel to illuminate at various intensities and wavelengths (e.g., combined wavelengths of the sub-pixels), effective to produce on-screen content (e.g., images). Such display panels are well-suited for electronic devices and are further appreciated by users, in large part, because of their image quality.

To provide users with large display experiences in small product form factors, manufacturers may design electronic devices, including at least portions of display panel stacks, to fold into one or more configurations (“foldable electronic devices”). A foldable electronic device, with a foldable display, can include one or more folding regions about which one or more non-folding regions may rotate. The non-folding regions may fold towards or away from each other to achieve one of a variety of foldable display shapes, such as a ‘Z’ shape or ‘C’ shape. One foldable display shape may be chosen over another foldable display shape based on design factors, such as having the foldable display on an inside or an outside of the foldable electronic device when in a folded position. Commonly, a foldable display includes one primary folding region that divides the display into two equal segments (e.g., non-folding regions) that are generally equidistant from the primary folding region.

Such foldable electronic devices are prized by users for their maximized display size and small form factor. However, these foldable electronic devices often include a trim (e.g., a bumper component) along a perimeter of the foldable display to protect a flexible display panel and thin glass layer. This trim can interfere with user interaction at a touch interface of foldable electronic devices and/or reduce a display active area. Moreover, some foldable electronic devices include an open-design hinge mechanism, which may expose internal components to external contaminants. These design features may reduce user experience and introduce mechanical and/or electrical risks to the product.

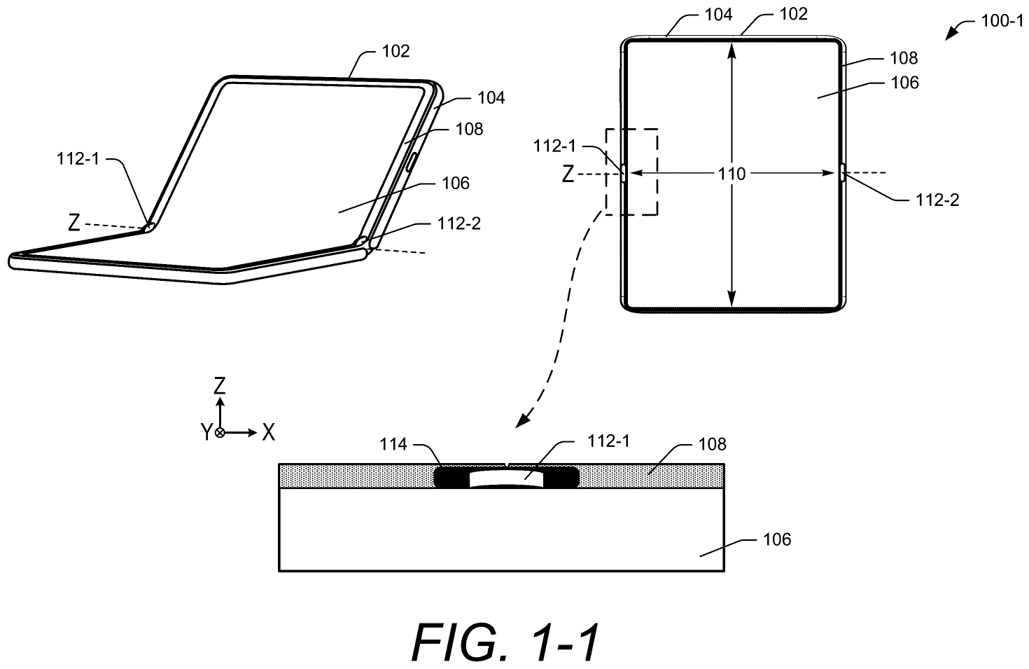

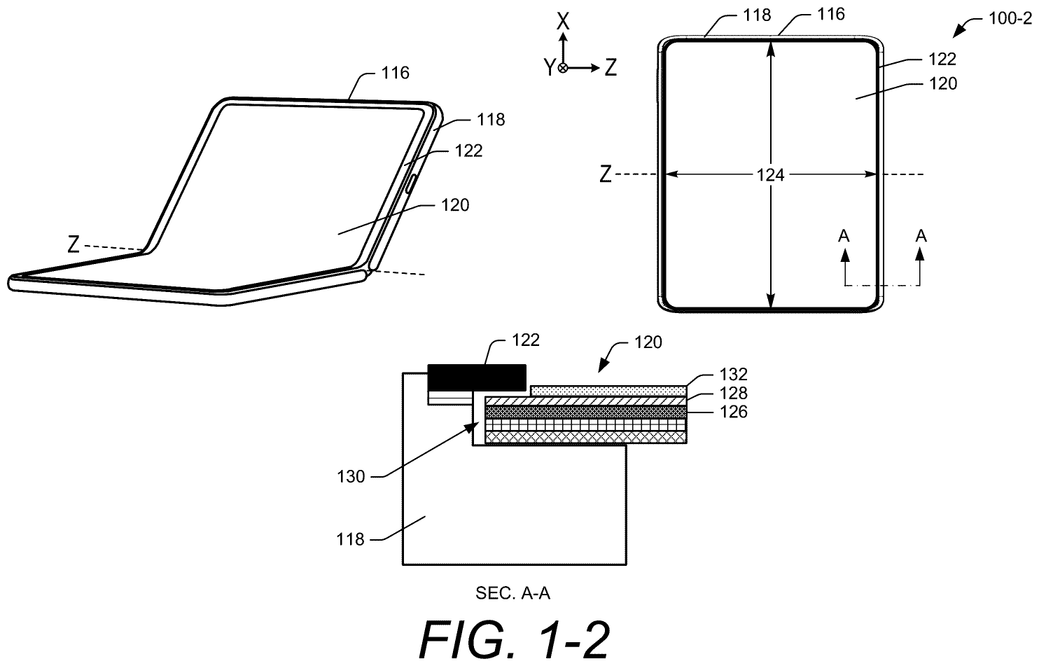

In one example, as illustrated in an example implementation 100-1 of FIG. 1-1, a foldable electronic device 102 includes an open-design hinge mechanism. In more detail, the foldable electronic device 102 may include a housing 104, a display 106 (e.g., a display panel stack), and a trim 108. The trim 108 may extend along a perimeter of the display 106, defining an active area 110 of the display 106. At one or more folding regions, the trim 108 may be absent to provide space for one or more hinge mechanisms 112 (e.g., a first hinge mechanism 112-1, a second hinge mechanism 112-2) and enable a folding of the foldable electronic device 102. Further, at one or more folding regions, the foldable electronic device 102 may include a gap 114, such that the one or more hinge mechanisms 112 can freely rotate to fold or unfold the foldable electronic device 102.

Although such a solution may be functional, the open-design hinge mechanism, including the gap 114, may have some limitations. For instance, the gap 114 may collect ingress contaminants, such as dust and water, which can harm mechanical components (e.g., the first hinge mechanism 112-1) and/or electrical components. Moreover, solid, ingress particles may accumulate in the gap 114, jamming the first hinge mechanism 112-1 and impeding the folding and unfolding of the foldable electronic device 102.

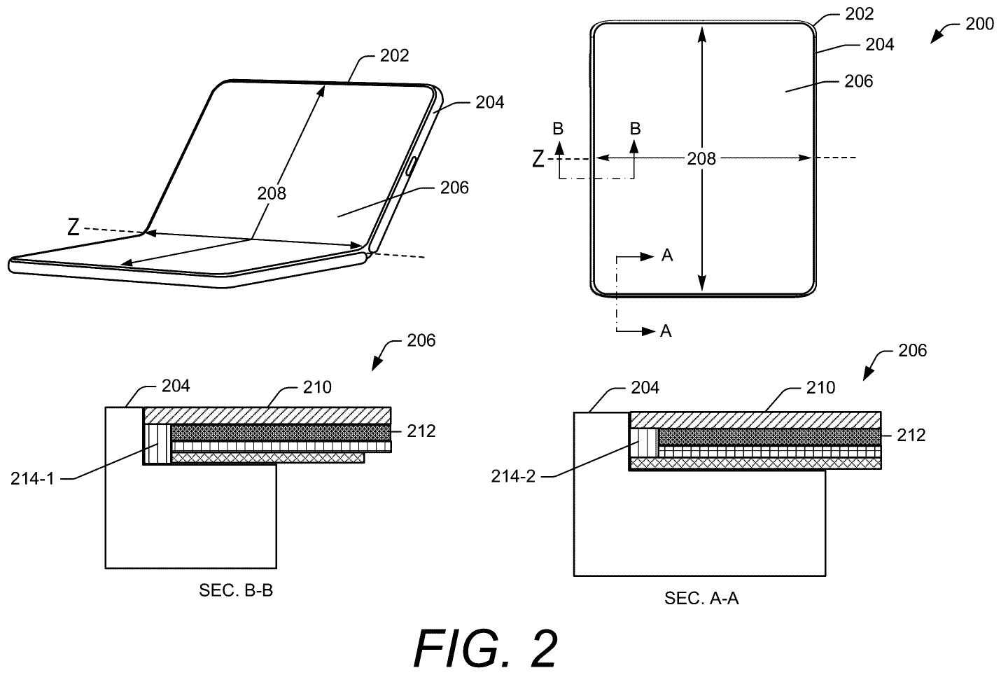

In another example, as illustrated in an example implementation 100-2 of FIG. 1-2, a foldable electronic device 116 includes a trim surrounding a perimeter of a display. In more detail, the foldable electronic device 116 may include a housing 118, a display 120, and a trim 122. The trim 122 may extend along a perimeter of the display 106, defining an active area 124 of the display 120.

Due to a delicacy of a display panel 126, at least portions of the display panel 126 may be positioned beneath a cover layer 128, as illustrated in section view A-A. Moreover, because sides of the display panel 126 may be particularly prone to damage, space 130 may be provided between the sides of the display panel 126 and the housing 118. To prevent ingress contaminants from entering the space 130 and to physically protect the display panel 126, the trim 122 may be positioned over the space 130 and at least portions of the display panel 126. Generally, the cover layer 128 for foldable electronic devices is implemented as an ultra-thin glass layer and a protective film 132 is disposed on a top surface of the cover layer 128.

Although such a solution may be functional, like the foldable electronic device 102 of FIG. 1-1, the foldable electronic device 116 of FIG. 1-2 may have limitations. For instance, the trim 122 may interfere with a user's interaction at a touch interface on the display 120. Further, the trim 122 may reduce a size of the active area 124 and detract from a borderless aesthetic design appeal of the foldable electronic device 116, reducing user experience.

To this end, this document describes systems and techniques directed at trimless foldable displays. In aspects, a foldable electronic device includes a foldable display structure having a cover layer and a display panel positioned thereunder. At least portions of the cover layer may extend beyond one or more edges of the display panel. The foldable electronic device may further include a first compliant material disposed (i) between the housing and the display panel and (ii) underneath the at least portions of the cover layer that extend beyond the one or more edges of the display panel. Through such an implementation, the display panel of the foldable electronic device may be protected by the cover glass and/or the first compliant material. As a result, the foldable electronic device can do away with a display trim that would otherwise surround a perimeter of the display.

### Example Implementations

The following discussion describes example implementations, techniques, apparatuses that may be employed in the example implementations, and various devices in which components of trimless foldable displays can be embodied. In the context of the present document, reference is made to the following by way of example only.

FIG. 2 illustrates an example implementation 200 of an example foldable electronic device 202 with a trimless foldable display in accordance with one or more implementations. As illustrated, the example foldable electronic device 202 includes a housing 204 (e.g., a frame) and a display 206 (e.g., a display panel stack). The foldable electronic device 202 may be configured to fold along one or more axes (e.g., a Z-axis). The foldable electronic device 202 includes an active area 208 defined by at least one of the housing 204 and an opaque border (not illustrated) added to a bottom face of a cover layer 210.

As illustrated in section view A-A and section view B-B, the display 206 of the foldable electronic device 202 includes the cover layer 210 (e.g., cover glass) and a display panel 212. In implementations, the cover layer 210 is exposed to an external environment surrounding the foldable electronic device 202. For example, the foldable electronic device 202 may not include a protective film. In further implementations, the cover layer 210 is a glass layer that includes a variable thickness along at least one dimension of the foldable electronic device 202 (e.g., a width of the device, along an axis perpendicular to a folding axis). In alternative implementations, the cover layer 210 is uniformly thick transparent material. The cover layer 210 protects the display panel 212 and serves as a barrier to ingress contaminants (e.g., dust, water). In such an implementation, and in comparison to other solutions (e.g., example implementation 100-2), the foldable electronic device 202 includes a cover layer 210 that is larger than the display panel 212 in at least one dimension (e.g., a length, a width) and extends to (e.g., abuts) the housing 204. Thus, the cover layer 210 may protect the display panel 212, including edges of the display panel 212, from environmental contaminants and external forces.

In addition, the foldable electronic device 202 may include a compliant material 214 (e.g., a first compliant material 214-1, a second compliant material 214-2) disposed between the housing 204 and at least portions of the display 206. This compliant material 214 may physically support the cover layer 210 and/or the display panel 212.

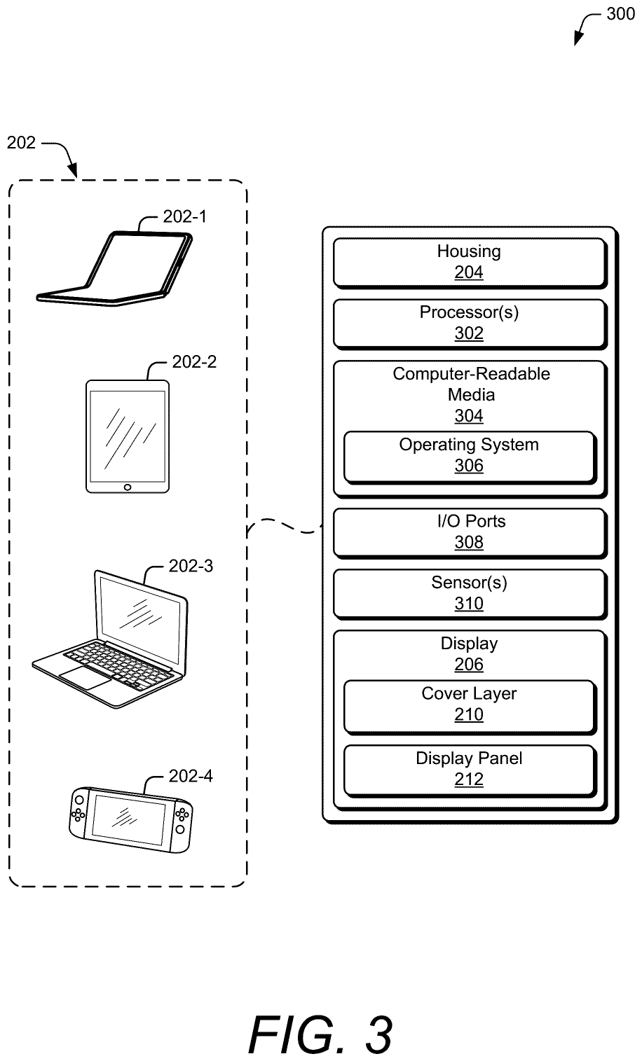

FIG. 3 illustrates example foldable electronic devices 202 in which trimless foldable displays can be implemented. The foldable electronic devices 202 may include additional components and interfaces omitted from FIG. 3 for the sake of clarity.

The foldable electronic devices 202 can be any of a variety of consumer electronic devices. As non-limiting examples, the foldable electronic device 202 can be a mobile phone 202-1, a tablet device 202-2, a laptop computer 202-3, a portable video game console 202-4, and the like.

The foldable electronic device 202 includes the housing 104, which defines at least one internal cavity within which one or more of a plurality of electronic components may be disposed. In implementations, a mechanical frame may define one or more portions of the housing 204. As an example, a mechanical frame can include plastic or metallic walls that define portions of the housing 204. In additional implementations, a mechanical frame may support one or more portions of the housing 204. As an example, one or more exterior housing components (e.g., plastic panels) can be attached to the mechanical frame (e.g., a chassis). In so doing, the mechanical frame physically supports the one or more exterior housing components, which define portions of the housing 204. In implementations, the mechanical frame and/or the exterior housing components may be composed of crystalline or non-crystalline solids.

These mechanical frames can be designed in a variety of configurations. In implementations the mechanical frame may be designed with a bucket architecture. As an example, a mechanical frame designed with a bucket architecture defines an open-sided polyhedron (e.g., an open-sided rectangular prism). In additional implementations, the mechanical frame may be designed with a mid-frame architecture. In either architecture, a mechanical frame may include more than one open side, defining a partial or full skeletal polyhedra (e.g., a polyhedron structure in which vertices and edges are defined by rods and two or more faces are absent). Exterior housing components (e.g., plastic panels) can then be attached to the mechanical frame to define an open-sided polyhedron. In any implementation, the housing 104 may be sealed through the inclusion of a display (e.g., the cover layer 210), defining at least one internal cavity.

The foldable electronic device 202 may further include one or more processors 302. The processor(s) 302 can include, as non-limiting examples, a system on a chip (SoC), an application processor (AP), a central processing unit (CPU), or a graphics processing unit (GPU). The processor(s) 302 generally execute commands and processes utilized by the foldable electronic device 202 and an operating system installed thereon. For example, the processor(s) 302 may perform operations to display graphics of the foldable electronic device 202 on the display 206 and can perform other specific computational tasks.

The foldable electronic device 202 may also include computer-readable storage media (CRM) 304. The CRM 304 may be a suitable storage device configured to store device data of the foldable electronic device 202, user data, and multimedia data. The CRM 304 may store an operating system 306 that generally manages hardware and software resources (e.g., the applications) of the foldable electronic device 202 and provides common services for applications stored on the CRM 304. The operating system and the applications are generally executable by the processor(s) 302 to enable communications and user interaction with the foldable electronic device 202. One or more processor(s) 302, such as a GPU, perform operations to display graphics of the foldable electronic device 202 on the display 106 and can perform other specific computational tasks. The processor(s) 302 can be single-core or multiple-core processors.

The foldable electronic device 202 may also include input/output (I/O) ports 308. The I/O ports 308 allow the foldable electronic device 202 to interact with other devices or users. The I/O ports 308 may include any combination of internal or external ports, such as universal serial bus (USB) ports, audio ports, Serial ATA (SATA) ports, PCI-express based ports or card-slots, secure digital input/output (SDIO) slots, and/or other legacy ports.

The foldable electronic device 202 may further include one or more sensors 310. The sensor(s) 310 can include any of a variety of sensors, such as an audio sensor (e.g., a microphone), a touch-input sensor (e.g., a touchscreen), an image-capture device (e.g., a camera, video-camera), proximity sensors (e.g., capacitive sensors), an under-display fingerprint sensor, or an ambient light sensor (e.g., photodetector). In implementations, the foldable electronic device 202 includes one or more of a front-facing sensor(s) and a rear-facing sensor(s).

Further, the foldable electronic device 202 includes the display 206 (e.g., a display panel stack) having the cover layer 210 and the display panel 212. The cover layer 210 may be implemented as any of a variety of transparent materials including polymers (e.g., plastic, acrylic) or glasses. The cover layer 210 may form any foldable, three-dimensional shape.

The display panel 212 may include a two-dimensional pixel array (not illustrated in FIG. 3) forming a grid, operably coupled to one or more row-line drivers via electrical traces. The pixel array emits light to create an image on the display panel 212 upon electrical activation by one or more drivers. As an example, data-line drivers provide voltage data via electrical traces to the pixel array to control a luminance of individual pixels.

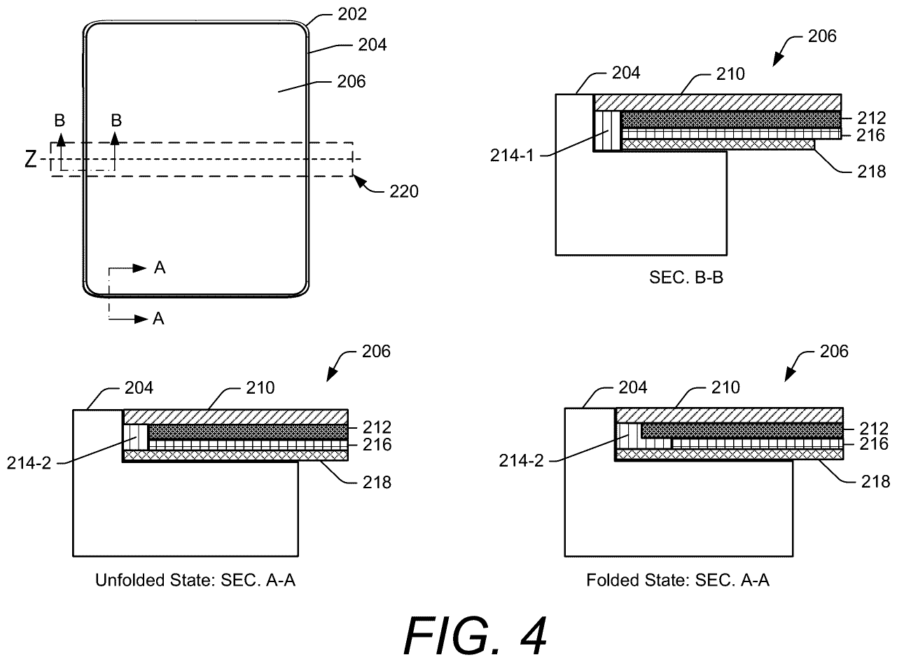

FIG. 4 illustrates three example section views of the example foldable electronic device 202 with a trimless foldable display in accordance with one or more implementations. As illustrated in all section views, the display 206 includes the cover layer 210, the display panel 212, a display support structure 216 (e.g., a steel display backing support), and an adhesive layer 218 (e.g., a pressure sensitive adhesive). At a folding region 220 of the foldable electronic device 202, as illustrated in section view B-B, the foldable electronic device 202 may include a first compliant material 214-1. The first compliant material 214-1 may surround a hinge mechanism. In implementations, the first compliant material 214-1 may be a potting material, such as a resin-based compound (e.g., an epoxy resin, a silicon gel, polyurethane resin). The potting material may provide mechanical support to the cover layer 210 (e.g., from an underside of the cover layer 210) and/or electrical insulation to the display panel 212, as well as prevent environmental contamination (e.g., ingress fluids). In addition, the potting material may provide vibration dampening and reduce stress on the display panel 212. In additional implementations, the first compliant material 214-1 may be substituted for a rubber gasket or a foam gasket. The rubber or foam gasket may be implemented as a hinge mechanism seal.

At non-folding regions of the foldable electronic device 202, as illustrated in section views A-A, the foldable electronic device 202 includes a second compliant material 214-2. When the foldable electronic device 202 is in an unfolded state, layers of the display 206 (e.g., display panel stack), such as the display panel 212 and the display support structure 216, may have aligned edges. However, when the foldable electronic device 202 is in a folded state, a radius of curvature for an outer layer (e.g., the display support structure 216) of the display 206 may be larger than a radius of curvature for an inner layer (e.g., the display panel 212), resulting in unaligned edges. Thus, the second compliant material 214-2 may be configured to undergo both tension and/or compression to accommodate a folding and unfolding of the foldable electronic device 202. The second compliant material 214-2 may provide mechanical support for the cover layer 210 (e.g., from an underside of the cover layer 210), support for the display panel 212 (e.g., from an underside of the display panel 212 when in the folded state), or electrical insulation to the display panel 212, as well as prevent environmental contamination (e.g., ingress fluids). In addition, the second compliant material 214-2 may provide vibration dampening and reduce stress on the display panel 212.

In implementations, the second compliant material 214-2 is a potting material, such as a resin-based compound. The potting material may be dispensed via liquid dispensation or foam dispensation and may be cured via ultraviolet radiation or thermal radiation.

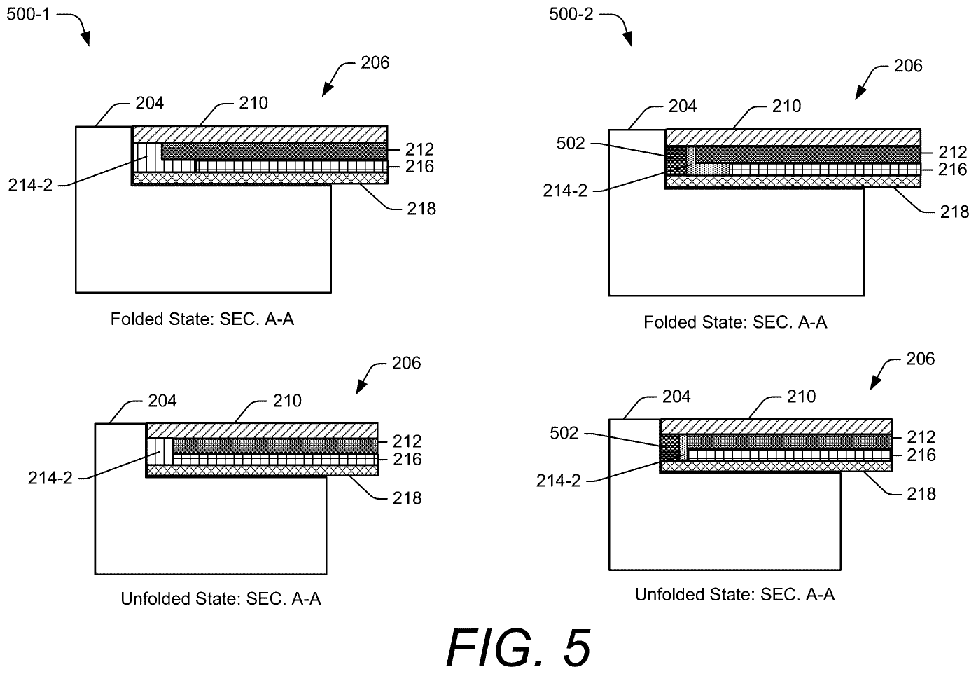

FIG. 5 illustrates two example implementations (e.g., first example implementation 500-1, second example implementation 500-2) for a foldable electronic device 202 having the second compliant material 214-2 in accordance with one or more implementations. As illustrated in the first example implementation 500-1, the foldable electronic device 202 includes only the second compliant material 214-2. The second compliant material 214-2 may be configured to undergo shearing stress (e.g., in the folded state) and still provide physical support (e.g., a normal force) to a bottom face of the cover layer 210 and a bottom face of the display panel 212. As illustrated in the second example implementation 500-2, the foldable electronic device 202 includes two separate but adjacent materials: a rigid material 502 and the second compliant material 214-2. Whereas the second compliant material 214-2 may expand and compress during folding and unfolding, respectively, the rigid material 502 may maintain a consistent size and shape. In such an implementation, the rigid material 502 provides reliable and consistent physical support (e.g., a normal force) to the bottom face of the cover layer 210. Further, the second compliant material 214-2, which accommodates for the folded state and the unfolded state of the foldable electronic device 202, provides physical support to the bottom face of the display panel 212 and the cover layer 210.

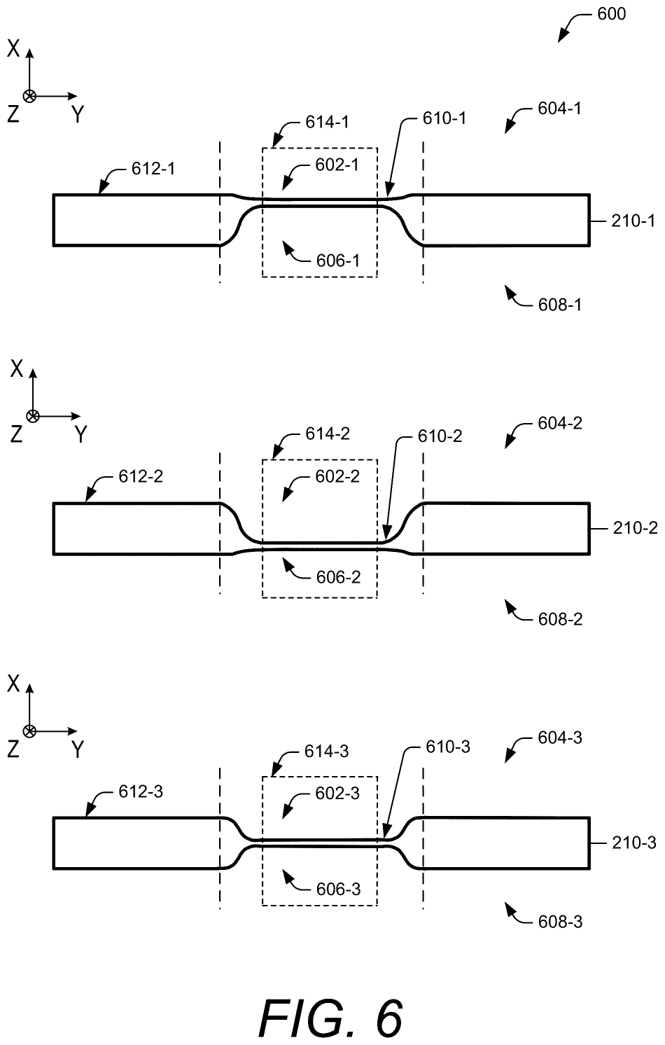

FIG. 6 illustrates three example implementations 600 of the cover layer 210 in accordance with one or more implementations. It will be understood by those skilled in the art that the three example implementations 600 are for example only and should not be considered as limitations. As illustrated, a first cover layer 210-1 includes a first groove 602-1 on a top face 604-1 and a second groove 606-1 on a bottom face 608-1 (e.g., the top face 604-1 being exposed to an ambient environment, the bottom face 608-1 positioned proximally closer to a display panel). For the first cover layer 210-1, the first groove 602-1 is shallower in depth than the second groove 606-1. In at least some implementations, a width of the first groove 602-1 is narrower than a width of the second groove 606-1. In still further implementations, the first groove 602-1 and the second groove 606-1 are aligned, for example, along an X-axis.

Further illustrated, the first groove 602-1 and the second groove 606-1 form a variable thickness in the first cover layer 210-1 along at least one dimension of the first cover layer 210-1 (e.g., a dimension perpendicular to a length of the groove, the Y-axis). The first groove 602-1 and the second groove 606-1 may define, in the first cover layer 210-1, a thin region 610-1 and at least one thick region 612-1. In implementations, a ratio of the dimensional-thickness between the thick region 612-1 and the thin region 610-1 may be at least six-to-one. In one example, the thick region 612-1 may be 200 micrometers thick, while the thin region 610-1 may be 30 micrometers thick. While other foldable display structures may utilize, for example, ultra-thin glass that is at most 70-100 micrometers thick, the first cover layer 210-1 may be much thicker, providing better reliability and hardness.

At least portions of the first groove 602-1 and the second groove 606-1 define a foldable region 614-1. For example, a portion of the thin region 610-1 may bend when mechanical forces are applied to the thick region 612-1. A thickness in the foldable region 614-1 and/or a thickness in non-folding regions at least partially determine a mechanical strength of the first cover layer 210-1.

Further illustrated, a second cover layer 210-2 includes a first groove 602-2 on a top face 604-2 and a second groove 606-2 on a bottom face 608-2 (e.g., the top face 604-2 being exposed to an ambient environment, the bottom face 608-2 positioned proximally closer to a display panel). For the second cover layer 210-2, the first groove 602-2 is greater in depth than the second groove 606-2. In at least some implementations, a width of the first groove 602-2 is wider than a width of the second groove 606-2. In still further implementations, the first groove 602-2 and the second groove 606-2 are aligned, for example, along an X-axis.

Further illustrated, the first groove 602-2 and the second groove 606-2 form a variable thickness in the second cover layer 210-2 along at least one dimension of the second cover layer 210-2 (e.g., a dimension perpendicular to a length of the groove, the Y-axis). The first groove 602-2 and the second groove 606-2 may define, in the second cover layer 210-2, a thin region 610-2 and at least one thick region 612-2. In implementations, a ratio of the dimensional thickness between the thick region 612-2 and the thin region 610-2 may be at least six-to-one. In one example, the thick region 612-2 may be 200 micrometers thick, while the thin region 610-2 may be 30 micrometers thick. While other foldable display structures may utilize, for example, ultra-thin glass that is at most 70-100 micrometers thick, the first cover layer 210-2 may be much thicker, providing better reliability and hardness.

At least portions of the first groove 602-2 and the second groove 606-2 define a foldable region 614-2. For example, a portion of the thin region 610-2 may bend when mechanical forces are applied to the thick region 612-2. A thickness in the foldable region 614-2 and/or a thickness in non-folding regions at least partially determine a mechanical strength of the second cover layer 210-2.

Further illustrated, a third cover layer 210-3 includes a first groove 602-3 on a top face 604-3 and a second groove 606-3 on a bottom face 608-3 (e.g., the top face 604-3 being exposed to an ambient environment, the bottom face 608-3 positioned proximally closer to a display panel). For the second cover layer 210-3, the first groove 602-3 is equal in depth to the second groove 606-3. In at least some implementations, a width of the first groove 602-3 is equal to a width of the second groove 606-3. In still further implementations, the first groove 602-3 and the second groove 606-3 are aligned, for example, along an X-axis. As illustrated, the third cover layer 210-3 may be symmetrical along two or more dimensions (e.g., a Z-axis, a Y-axis).

Further illustrated, the first groove 602-3 and the second groove 606-3 form a variable thickness in the third cover layer 210-3 along at least one dimension of the third cover layer 210-3 (e.g., a dimension perpendicular to a length of the groove, the Y-axis). The first groove 602-3 and the second groove 606-3 may define, in the third cover layer 210-3, a thin region 610-3 and at least one thick region 612-3. In implementations, a ratio of the dimensional thickness between the thick region 612-3 and the thin region 610-3 may be at least six-to-one. In one example, the thick region 612-3 may be 200 micrometers thick, while the thin region 610-3 may be 30 micrometers thick. While other foldable display structures may utilize, for example, ultra-thin glass that is at most 70-100 micrometers thick, the third cover layer 210-3 may be much thicker, providing better reliability and hardness.

At least portions of the first groove 602-3 and the second groove 606-3 define a foldable region 614-3. For example, a portion of the thin region 610-3 may bend when mechanical forces are applied to the thick region 612-3. A thickness in the foldable region 614-3 and/or a thickness in non-folding regions at least partially determine a mechanical strength of the third cover layer 210-3.

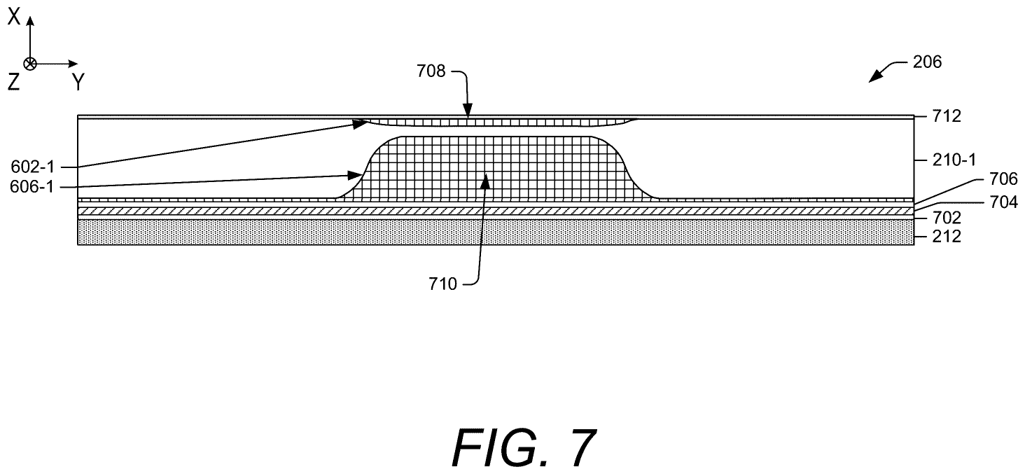

FIG. 7 illustrates an example implementation of the display 206 with more detail in accordance with one or more implementations. As illustrated, the display 206 includes the first cover layer 210-1 (for example only and not by way of limitation) and the display panel 212. The display 206 may further include a permanent optically-clear adhesive layer 702, which adheres the display panel 212 to a permanent protective layer 704. In implementations, the permanent optically-clear adhesive layer 702 and the permanent protective layer 704 are configured to remain affixed to the display panel 212 when, for example, the first cover layer 210-1 is removed for service. Thus, the permanent optically-clear adhesive layer 702 may include a stronger bond than, for example, a removable optically-clear adhesive layer 706. The removable optically-clear adhesive layer 706 may be deposited on a face of the permanent protective layer 704 opposite of the permanent optically-clear adhesive layer 702.

In aspects, the first groove 602-1 and the second groove 606-1 of the first cover layer 210-1 are filled with a first resin 708 and a second resin 710, respectively. In implementations, the first resin 708 is contiguous with the top face 604-1 (not labeled in FIG. 4) of the first cover layer 210-1. For example, the first resin 708 is flush with a surface of the top face 604-1. In further implementations, the second resin 710 extends beyond the second groove, covering an entire surface of the bottom face 608-1 (not labeled in FIG. 4). For example, the second resin 710 is disposed between all portions of the permanent protective layer 704 and the first cover layer 210-1. In at least some implementations, the second resin 710 fills only the second groove 606-1 such that the second resin 710 is contiguous with the bottom face 608-1.

In implementations, the first resin 708 includes a compression-cyclable resin. The compression-cyclable resin includes a compression-survivable index matched resin. In further implementations, the second resin 710 comprises a tension-cyclable resin. The tension-cyclable resin includes a tensile-survivable index matched resin. In alternative implementations, the first resin 708 and the second resin 710 are identical.

The display 206 may further include a hard-coating 712. Although illustrated in FIG. 4 as a separate and distinct portion of the display 206, it will be understood by those skilled in the art that the hard-coating 712 is not a layer (e.g., like a protective film), but a coating. Thus, the first cover layer 210-1 is said to be user-exposed (e.g., exposed to an external environment) since a user may directly interact with the first cover layer 210-1 and hard-coating 712 as opposed to a protective film or the like.

The hard-coating 712 may be a thin coat of hard and transparent material composed of substances like silicon dioxide. The hard-coating 712 may improve scratch resistance and durability. The hard-coating 712 may also be applied to the first resin 708.

### CONCLUSION

Unless context dictates otherwise, use herein of the word “or” may be considered use of an “inclusive or,” or a term that permits inclusion or application of one or more items that are linked by the word “or”. Also, as used herein, a phrase referring to “at least one of” a list of items refers to any combination of those items, including single members. For instance, “at least one of a, b, or c” can cover a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c, or any other ordering of a, b, and c). Further, items represented in the accompanying Drawings and terms discussed herein may be indicative of one or more items or terms, and thus reference may be made interchangeably to single or plural forms of the items and terms in this written description.

Although implementations directed at trimless foldable displays have been described in language specific to certain features and/or methods, the subject of the appended Claims is not necessarily limited to the specific features or methods described. Rather, the specific features and methods are disclosed as example implementations directed at trimless foldable displays.

What is claimed is:

1. A foldable electronic device comprising:
a housing having a first folding region that intersects a first non-folding region and a second non-folding region, at least one of the first non-folding region or the second non-folding region configured to rotate about the first folding region;
a foldable display structure positioned within at least portions of the first non-folding region and the second non-folding region of the housing, the foldable display structure comprising:
a display panel, the display panel having a top face within which a plurality of light-emitting pixels are disposed; and
a cover layer positioned as a topmost layer of a foldable display structure, the cover layer having a top face and a bottom face, the bottom face of the cover layer having an area larger than an area of the top face of the display panel such that at least portions of the cover layer extend beyond one or more edges of the display panel; and
a first compliant material disposed (i) between the housing and the display panel and (ii) underneath the at least portions of the cover layer that extend beyond the one or more edges of the display panel.

2. The foldable electronic device of claim 1, wherein the first compliant material is disposed in the first folding region.

3. The foldable electronic device of claim 2, further comprising:
a second compliant material disposed in at least one of the first non-folding region or the second non-folding region of the housing.

4. The foldable electronic device of claim 3, wherein the first compliant material and the second compliant material comprise a resin-based compound.

5. The foldable electronic device of claim 3, wherein the second compliant material is configured to provide a normal force to the bottom face of the cover layer sufficient to provide mechanical support.

6. The foldable electronic device of claim 3, wherein the second compliant material is configured to withstand a shearing stress when at least one of the first non-folding region or the second non-folding region are rotated about the first folding region orienting the foldable electronic device in an unfolded state.

7. The foldable electronic device of claim 3, further comprising:
a rigid material disposed in at least one of the first non-folding region or the second non-folding region of the housing, and wherein the rigid material is disposed (i) between the housing and the second compliant material and (ii) underneath the at least portions of the cover layer that extend beyond the one or more edges of the display panel.

8. The foldable electronic device of claim 2, wherein the first compliant material comprises a rubber gasket or a foam gasket.

9. The foldable electronic device of claim 1, wherein the cover layer comprises:
a first groove on the top face of the cover layer along a first plane; and
a second groove on the bottom face of the cover layer along the first plane, the first groove and the second groove forming a variable thickness in the cover layer along a dimension of the cover layer perpendicular to the first plane sufficient to define the first folding region.

10. The foldable electronic device of claim 9, wherein the cover layer further comprises:
a first resin deposited within the first groove, the first resin contiguous with the top face of the cover layer; and
a second resin deposited within the second groove.

11. The foldable electronic device of claim 9, wherein the first groove and the second groove forming the variable thickness in the cover layer along the dimension of the cover layer perpendicular to the first plane define a thick region and a thin region in the cover layer, and wherein the variable thickness between the thick region and the thin region comprises a ratio of at least six-to-one.

12. The foldable display structure of claim 9, wherein:
the first groove comprises a first depth shallower than a second depth of the second groove; and
the first groove comprises a first width narrower than a second width of the second groove.
